(19) United States
(12) Patent Application Publication
(10) Pub. No.: US 2013/0059132 A1
(43) Pub. Date: Mar. 7, 2013

(54) Laminate Having a One-Dimensional Composite Structure

(71) Applicants: Oral Cenk Aktas, Saarbruecken (DE); Michael Veith, St. Ingbert (DE); Juseok Lee, Saarbruecken (DE); Hakima Smail, Muenchen (DE); Marina Martinez Miró, Saarbruecken (DE)

(72) Inventors: Oral Cenk Aktas, Saarbruecken (DE); Michael Veith, St. Ingbert (DE); Juseok Lee, Saarbruecken (DE); Hakima Smail, Muenchen (DE); Marina Martinez Miró, Saarbruecken (DE)

(73) Assignee: Leibniz-Institut fuer neue Materialien gemeinnuetzige GmbH, Saarbruecken (DE)

(21) Appl. No.: 13/698,074

(22) PCT Filed: May 25, 2011
(86) PCT No.: PCT/EP2011/002598

§ 371 Date: Nov. 15, 2012

(30) Foreign Application Priority Data
May 27, 2010 (DE) 10 2010 021 691.7

(51) Int. Cl. B32B 7/14; B29C 41/42; B32B 37/12; B32B 37/00; B32B 15/04; C23C 16/458

(52) U.S. Cl. 428/198; 428/457; 428/336; 118/728; 118/725; 427/248.1; 156/60; 264/261; 264/334

(57) ABSTRACT

A laminate includes two substrates that are connected by means of a bonding layer, the bonding layer enabling a one-dimensional composite structure. This enables a purely inorganic compound of different materials and a significantly improved connection when using adhesives.

### FIELD OF THE INVENTION

The invention relates to coatings comprising an inorganic one-dimensional composite structure, and to composite materials comprising same.

Structures on surfaces on the micrometer and/or nanometer scale play a large role in current research. This concerns, in particular, fiberlike structures, which are known from nature in the area of dry adhesion, in the case of geckos, for example. Surfaces structured in such a way allow adhesion to any desired surfaces without the aid of an adhesive agent, by virtue of the van-der-Waals' forces which occur. Examples of such structures are described in WO 01/49776 A2, for example.

The majority of such structures are obtained from organic materials. For instance, U.S. Pat. No. 6,099,960 describes the production of fibers in the nanometer range that may also have been coated.

At the same time the problem exists that it is very difficult to join certain materials adhesively to one another. Usually for this purpose at least one adhesive agent is used. Nevertheless, the resulting laminates either do not hold particularly well, or cannot be used for many different materials. Especially if inorganic materials are to be joined adhesively to one another, or inorganic materials are to be joined adhesively to organic materials.

The applicant's application DE 10 2006 013 484 A1 describes the production of an element/element oxide composite material, in other words a material which comprises at least one element and the corresponding element oxide. The application discloses a composite material of this kind in the form of nanowires, which consist of a metal core surrounded by an oxide shell. They can be produced in a simple way by chemical vapor deposition (CVD).

### OBJECT

It is an object of the invention to provide a laminate comprising at least two substrates that makes it possible to mediate the adhesion between substrates. The laminate can be produced in a simple way and allows adjoining of different substrates, more particularly of inorganic substrates, also in the form of a purely inorganic connection. A further object of the invention is to specify a method for joining at least two substrates.

### Achievement

This object is achieved by the inventions with the features of the independent claims. Advantageous developments of the inventions are characterized in the dependent claims. The wording of all of the claims is hereby made part of the content of this description, by reference. The invention also embraces all reasonable combinations, and more particularly all of the stated combinations, of independent and/or dependent claims.

The object is achieved by means of a laminate comprising at least two substrates, there being disposed between the two substrates a bonding layer which comprises at least one-dimensional composite structure. An assembly of this kind is normally obtained by contacting surfaces of both substrates, with at least one of the surfaces having a one-dimensional composite structure prior to said contacting. The laminate then forms together with these surfaces. Contacting here may be a mechanical pressing against one another; alternatively, contacting may be by a chemical reaction—for example, synthesis of at least one one-dimensional composite structure—between the surfaces.

A one-dimensional composite structure here is a composite made up of a metallic core and a metal oxide shell. The one-dimensional composite structure may comprise or consist of one or more nanowires of the construction described. Besides these simple, linear, cable like, one-dimensional structures, the one-dimensional composite structure may alternatively or additionally comprise or consist of one or more branched structures, composed of a plurality of linear-form nanowires which have grown onto one another in a branchlike way. These two forms may also be referred to as linear and branched nanowires, respectively. In the case of the branched form, the metallic cores of the wires may contact one another at the branching sites, or the metal cores may be separated from one another at the branching sites by the metal oxide shell. The one-dimensional composite structure is located on a substrate.

The nanowires possess, in particular, two dimensions, which are in the range below 200 nm; for example, in the range from 1 to 200 nm and preferably from 10 to 100 nm, more particularly about 20 to 40 nm. The ratio of width to length of the nanowires is generally at least 1:3 and preferably at least 1:5. The third dimension is generally situated in the micrometer or submicrometer range. Accordingly, the composites are referred to in the sense of the invention as being one-dimensional, since only one of their dimensions is not situated in the range of less than one micrometer. The cross section of the nanowires is generally approximately circular. The nanowires of the coating here are between 2 and 10 μm long.

A bonding layer is a layer which is disposed between two other materials and which joins the two materials such that they are adhesively bonded. In the sense of the specification, this is also referred to as a laminate. This does not mean that the two substrates are themselves layers, such as sheets, for example. The laminate may therefore also be referred to as an assembly of materials.

In one preferred embodiment of the invention, the bonding layer comprises a one-dimensional composite structure comprising a metal and a metal oxide, the metal being selected from the group containing Al, Ga, In or Tl. Preference is given to a one-dimensional composite structure of aluminum and aluminum oxide.

The one-dimensional composite structure may contain small amounts of impurities, for example, <2% of carbon, for example, in the form of carbides such as Al₄C₃. More particularly, however, the structure is free from residues of templates or catalysts.

Preferred nanowires are those of the kind already known from DE 10 2006 013 848 A1, the content of that specification being referenced explicitly.

The one-dimensional composite structure is preferably obtained by a MOCVD process (metal organic chemical vapor deposition).

Individual process steps are described in more detail below. The steps need not necessarily be carried out in the order stated, and the process described may also have further steps, not identified.

In a first step, metal-organic precursors are converted to the gas phase and subjected to thermolytic decomposition, with the nonvolatile decomposition product generally depositing at or on the substrate. The precursors used in the invention possess the general formula

El(OR)ₙH₂

where El is Al, Ga, In, Tl, Si, Ge, Sn, Pb or Zr, and R is an aliphatic or alicyclic hydrocarbon radical, and n, depending on the valence of El has a value of 1 or 2.

The aliphatic and alicyclic hydrocarbon radical is preferably saturated and possesses, for example, a length of 1 to 20 C atoms. Preference is given to alkyl or unsubstituted or alkyl-substituted cycloalkyl. The alkyl radical possesses preferably 2 to 15 C atoms, more preferably 3 to 10 C atoms, and may be linear or branched, with branched alkyl radicals being preferred. Examples that may be given here include the following: ethyl, n-propyl, n-butyl, and the corresponding higher linear homologs, isopropyl, sec-butyl, neopentyl, neohexyl, and the corresponding higher isoalkyl and neoalkyl homologs, or 2-ethylhexyl. The alicyclic rings may comprise one, two or more rings, each of which may be substituted by alkyl. The alicyclic radical possesses preferably 5 to 10, more preferably 5 to 8, C atoms. Examples that may be given include the following: cyclopentyl, cyclohexyl, methylcyclohexyl, norbornyl, and adamantyl.

Employed with preference in accordance with the invention are oxide compounds which form ceramic oxides.

Particularly preferred are aluminum alkoxy dihydrides which contain branched alkoxy radicals having 4 to 8 C atoms, more particularly aluminum tert-butoxydihydride. The preparation of such compounds is described in DE 195 29 241 A1. They can be obtained, for example, by reaction of aluminum hydride with the corresponding alcohol in a 1:1 molar ratio, with the aluminum hydride being preparable in situ by reaction of an alkali metal aluminum hydride with an aluminum halide. Moreover, the preparation of such compounds is also described by Veith et al. (Chem. Ber. 1996, 129, 381-384), and it is also shown that the compounds of the formula El(OR)H₂ may also comprise dimeric forms, such as (El(OR)H₂)₂, for example. Particularly preferred is (^{t}BuOAlH₂)₂.

The compounds are preferably converted to the gas phase and subjected to thermolytic decomposition, with the nonvolatile decomposition product generally being formed at or on a substrate in the form of the element/element oxide composite structure. Substrates contemplated for the application of the coating include all customary materials, examples being metal, ceramic, alloys, quartz, glass or glasslike materials which are preferably inert toward the starting products and end products. The thermolysis may be carried out, for example, in an oven, at an inductively heated surface, or at a surface located on an inductively heated sample carrier. In the case of inductive heating, it is possible to use merely conductive substrates, such as metals, alloy or graphite, for example. In the case of substrates with low conductivity, an electrically conducting substrate carrier or oven ought to be used in the case of inductive heating. Heating of the substrate may also take place by means of microwaves or lasers. The substrate may therefore be not only a surface of the reaction chamber but also a substrate placed therein. The reactor chamber used may be of any desired design and may consist of any customary inert material—for example, Duran glass or vitreous silica. Reactor chambers with hot or cold walls may be used. The heating may be electrical or by other means, preferably with the aid of a radiofrequency generator. The oven, and also the substrate carrier, may have any desired shapes and sizes, corresponding to the nature and shape of the substrate to be coated; accordingly, for example, the substrate may be a plate, a planar surface, and may be tubular, cylindrical or cuboidal, or may have a more complex shape.

It may be advantageous, before introducing the precursor, to flush the reactor chamber repeatedly with an inert gas, preferably nitrogen or argon. It may also be of advantage, optionally, to apply an interim vacuum, in order to render the reactor chamber inert.

Furthermore, it may be advantageous, before introducing the metal-organic precursor, to heat the substrate to be coated—for example, metal, alloy, semiconductor, ceramic, quartz, glass, or glasslike substrate—to more than 500° C., in order to clean the surface.

The desired element/element oxide composite structure comes about preferably at temperatures of more than 400° C., more preferably more than 450° C. Preference is given to temperatures of not above 1200° C., more particularly not more than 600° C., for example, 400° C. to 1200° C., and preferably 450° C. to 650° C., with particular preference 450° C. to 600° C. The substrate on or at which the thermolysis takes place is heated, accordingly, to the desired temperature. The generation of the element/element oxide composite structure of the invention is independent of the substrate material used and of its constitution.

The (metal organic) compound, or precursor, may be introduced into the reactor from a reservoir vessel, which is preferably conditioned thermally to a desired vaporization temperature. Thus, for example, the vessel may have been conditioned thermally to a temperature of between −50° C. and 120° C., preferably between −10° C. and 40° C. The thermolysis in the reactor chamber takes place in general at an underpressure of 10⁻⁶ mbar to atmospheric pressure, preferably in a range from 10⁻⁴ mbar to 10⁻¹ mbar, more preferably 10⁻⁴ mbar to 10⁻² mbar, very preferably between 5·10⁻² mbar and 2·10⁻² mbar. For the purpose of generating the vacuum, a vacuum pump system may be connected to the reactor on the output side. All conventional vacuum pumps can be used, preference being given to a combination of a rotary vane pump and a turbomolecular pump, or to a rotary vane pump. It is useful for the reservoir vessel for the precursor to be mounted on the side of the reactor chamber, and for the vacuum pump system to be mounted on the other side.

When the substrate is heated by induction it is possible for electrically conducting metal platelets or foils of square centimeter size to be disposed as substrate in a reaction tube composed of Duran glass or vitreous silica. If the apparatus dimensions are adapted, substrate surface areas in the range from square decimeters up to several square meters are also possible. Connected to the reaction tube are, on the input side, the reservoir vessel with the precursor, thermally conditioned to the desired vaporization temperature, and, on the output side, a vacuum pump system. The reaction tube is situated in a radiofrequency induction field which is used to heat the substrate platelets or foils to the desired temperature. When the desired pressure has been set and the precursor has been introduced, the substrate becomes covered with the element/element oxide composite structure.

It is advantageous to regulate the flow rate of the precursor, using a valve. The valve may be controlled manually or automatically.

By varying one or more operating parameters selected from substrate temperatures, gas pressure, precursor reservoir temperature, precursor flow rate (amount of precursor introduced per unit time), and vapor deposition time it is possible to control the morphology of the element/element oxide composite structure.

In order to obtain the composite structure of the invention a vapor deposition time of up to 10 minutes, preferably below 5 minutes, more preferably between 1 and 5 minutes or from 10 to 60 minutes, is implemented at a temperature of between 450° C. and 600° C. under a pressure of between 1·10⁻² to 10·10⁻² mbar, preferably between 2·10⁻² to 5·10⁻² mbar.

Substrates used may be various materials, examples being metal, alloy, semiconductor, ceramic, quartz, glass, or glasslike material; preferred substrates are metals or alloys, such as aluminum, copper, stainless steel, iron, chromium-plated surfaces, and glass or glasslike substrates.

In a further embodiment, the bonding layer comprises an adhesive agent or bonding agent. This can be achieved by applying the adhesive agent to the one-dimensional composite structure which has been applied to the surface of one of the substrates, and contacting this surface of the substrate with the surface of the second substrate, to which the adhesive agent or bonding agent has been applied. This forms the laminate having a bonding layer with a one-dimensional composite structure, and having an adhesive agent or bonding agent.

As a result of this there is an interaction between the one-dimensional composite structure and the adhesive or bonding agent. With advantage, the adhesive agent is already cured in the bonding layer.

The adhesive agent may have been applied to a second substrate. Interaction with the one-dimensional composite structure may be achieved in that case by bringing the surface of the second substrate, coated with the adhesive or bonding agent, into contact with a one-dimensional composite structure on the surface of the first substrate.

In this way the bonding layer preferably has a layer construction. Starting from the surface of the first substrate, there is optionally a layer of a one-dimensional composite structure. Above it lies a region which encompasses the one-dimensional composite structure and the adhesive agent. Above this, and up to the surface of the second substrate, the bonding layer consists of the adhesive agent. The bonding layer may also comprise further layers.

As adhesive agent or bonding agent it is possible to use adhesives that are known to the skilled person. These may be one-part, two-part or multipart adhesives. They are, for example, acrylate dispersions, polymethyl methacrylates, polyvinyl acrylates, polyesters, polyurethanes, natural rubber or synthetic rubber compositions, or silicones. They may also be copolymers.

Adhesive or bonding agents typically consist of an elastomer, a tackifying resin, a plasticizer, and a phenolic antioxidant. Elastomer may be natural rubber, styrene-diene block copolymers, more particularly styrene-isoprene-styrene block copolymers. Plasticizers used are generally mineral oils.

The adhesive agent may be a curable adhesive agent, which can be cured, for example, by heat or by irradiation—UV radiation, for example.

In a further embodiment the adhesive agent is a pressure-sensitive adhesive agent, of the kind used in self-adhesive tapes, for example. Adhesive agents of this kind are known to the skilled person.

Surprisingly it has now been found that the structure of the coating, comprising a one-dimensional composite structure, has a great influence on the adhesion of adhesive agents applied to said coating. The mechanism involved here is not the dry adhesion known from the gecko, but instead the interactions between an adhesive agent and the one-dimensional composite structure, or the adhesion between two substrates, mediated by a coating comprising a one-dimensional composite structure and an adhesive or bonding agent.

The inorganic one-dimensional composite structure is also markedly stiffer than the organic structures which are required for dry adhesion. Thus the structures do not exhibit dry adhesion. The structure, density, and thickness of the one-dimensional composite structure may be controlled, as already described, for example, through the duration of the thermal decomposition.

Accordingly, a thermal decomposition of the precursor for only one to five minutes leads only to a low level of coverage of the substrate with the one-dimensional composite structure. A longer thermal decomposition leads to a denser covering of the surface of the substrate with the one-dimensional composite structure. In contrast to dry adhesion it has now been found that the adhesion of a substrate which is joined via an adhesive layer to the substrate coated with the one-dimensional composite structure can be controlled through the structure of the one-dimensional composite structure. This means that the adhesion within a corresponding laminate having a bonding layer with a one-dimensional composite structure and having an adhesive agent or bonding agent can be controlled through the one-dimensional composite structure. In the case of a low level of coverage there is a sharp increase in adhesion. The two substrates—mediated through the bonding layer—bond to one another significantly more effectively than with a bonding layer only having the adhesive agent or bonding agent.

The thickness of the one-dimensional composite structure in the bonding layer is advantageously below 300 nm, preferably below 150 nm. It may be between 50 nm and 300 nm, preferably between 50 and 150 nm. The thickness of this bonding layer is preferably between 300 nm and 100 μm, more preferably between 10 μm and 50 μm. The composite structure may be present only in part of the bonding layer.

The longer the thermal decomposition of the precursor is carried out, i.e., the thicker and more pronounced the one-dimensional composite structure becomes, the greater the decrease in the adhesion of a second substrate, mediated by a bonding layer with an adhesive agent or bonding agent, and the one-dimensional composite structure. Without being tied to any particular theory, it is assumed that with increasing thickness of the one-dimensional composite structure, detachment of the second substrate is also accompanied by removal of part of the one-dimensional composite structure from the first substrate as well. The decrease in adhesion, accordingly, would not derive from a decrease in the adhesion between adhesive agent and one-dimensional composite structure. Instead, there is a detachment of the composite structure, i.e., of the bonding layer, from the first substrate.

This is in contrast to dry adhesion, where an increase in the surface area also leads to an increase in the adhesion. It is, instead, of critical importance that the one-dimensional composite structure is designed in a particular way.

For bonding layers which have an adhesive agent and/or bonding agent, therefore, a one-dimensional composite structure having a thickness of below 300 nm is preferred, more preferably below 150 nm.

The one-dimensional composite structure allows a sharp increase in the intersubstrate adhesion mediated by adhesive agents. In this context it is an actual advantage that the one-dimensional composite structure can be generated simply in one step specifically on inorganic substrates. In this way it is possible to produce composites of materials which are normally difficult to bond adhesively, such as, for example, glass, metals, and ceramics, with organic substrates.

In a further embodiment of the invention, the bonding layer consists only of inorganic constituents. This means that the two substrates are held together by a purely inorganic layer. With advantage, the bonding layer consists only of at least one one-dimensional composite structure.

The bonding layer in this case preferably has a thickness of not more than 20 μm, more preferably not more than 15 μm. The thickness may be at least 500 nm, preferably at least 1 μm. A layer thickness of between 1 μm and 15 μm is preferred.

One-dimensional composite structures of this kind are obtainable by the method described above if the duration of the thermal decomposition is more than 10 minutes, preferably more than 30 minutes. Depending on the desired thickness of the layer, coating may also last for a number of hours, as for example 5 hours, with preference being given to thermal decomposition of 10 to 60 minutes. The thermal decomposition takes place with advantage on both substrates.

By this means it is possible to join substrates via a purely inorganic layer.

Suitable substrates in this case are all materials which withstand the thermal decomposition. These are, in particular, the substrates which were recited for the production of the one-dimensional composite structure.

The invention additionally relates to a method for producing a laminate having at least two substrates, with controlled adhesion between the substrates. In this method, in a first step as described above, a one-dimensional composite structure is generated on a first substrate by thermal decomposition.

In a second step, the one-dimensional composite structure produced is contacted with an adhesive agent, which may have been applied to the surface of a second substrate, or which is contacted with the second substrate in a further step. This may be simple application, such as brushing, spraying, or knife-coating. It is also possible, however, for the second substrate to be a substrate coated with the adhesive agent.

Through the conditions of the thermal decomposition, selected from pressure, temperature and duration of thermal decomposition, it is possible in a simple way to control the extent of the adhesion, mediated by the laminate, between the at least two substrates. As already stated, it is in particular the duration of the thermal decomposition that determines the force of adhesion of the resultant bonding layer.

Second substrates contemplated include all kinds of materials. They may be organic or inorganic materials. They may be natural or synthetic materials.

The substrate in question may also be a substrate likewise coated with a one-dimensional composite structure. In that case the two substrates are joined to one another via the layer of adhesive or bonding agent.

Similarly, the applied second substrate may have been coated on another surface with an adhesive or bonding agent. This may be, for example, a double-sided adhesive tape. Again, a substrate coated with a one-dimensional composite structure may be applied to the second side of the adhesive tape.

The possibility of obtaining a laminate with controlled adhesion, especially with inorganic substrates, in a simple way opens up a host of possible applications. Since the one-dimensional composite structure can be applied to numerous substrates, especially inorganic substrates, such as ceramic, metals or glass, it is possible to bond combinations of materials adhesively in a significantly improved way. Examples might include the application of thin sheets to metal or glass surfaces. The second substrates may be, for example, textiles, such as woven fabrics, knitted fabrics, fiber mats, nonwoven mats, felts, carpets or knitwares. The textile fibers may be organic or inorganic fibers.

The substances in question may also be building materials, such as masonry, for example, made from stone, bricks, lime-sand blocks, concrete, plaster, tiles, clinker or gypsum boards.

Examples of metals or metal alloys are steel, including stainless steel, chromium, copper, titanium, tin, zinc, brass, and aluminum. An example of the semiconductor is silicon. Examples of glass are soda-lime glass, borosilicate glass, lead crystal, and fused silica. The glass in question may be, for example, flat glass, hollow glass such as container glass, or laboratory glasswares. The ceramic is, for example, a ceramic based on the oxides SiO₂, Al₂O₃, ZrO₂, or MgO, or on the corresponding mixed oxides.

Examples of the plastic—which, like the metal as well, may be present in thin sheet form—are polyethylene, e.g., HDPE or LDPE, polypropylene, polyisobutylene, polystyrene, polyvinyl chloride, polyvinylidene chloride, polyvinylbutyral, polytetrafluoroethylene, polychlorotrifluoroethylene, polyacrylates, polymethacrylates such as polymethyl methacrylate, polyamide, polyethylene terephthalate, polycarbonate, regenerated cellulose, cellulose nitrate, cellulose acetate, cellulose triacetate (TAC), cellulose acetate butyrate or rubber hydrochloride.

It is of course possible for the substrate to have been pretreated or provided with at least one surface layer. Such surface layers may consist of the materials specified above. The surface layer may be, for example, a metallization, an enameling, a glass layer, or a ceramic layer.

The substrate may take the form, for example, of plates, tubes, housings, bodyworks, walls, ceilings, thin sheets, textiles such as nonwovens, etc.

Depending on their stability in relation to the conditions of MOCVD, the second substrates may also be used as substrates for the one-dimensional composite structure.

Laminates with metallic and ceramic substrates are preferred.

The laminates of the invention can be used in numerous areas. Examples are applications such as working appliances and parts thereof, apparatus, articles and machines for use in commerce or industry, and research and laboratory, and parts thereof, means of locomotion and means of transport and parts thereof, household articles and working appliances for the household, and parts thereof, equipment, apparatus and accessories for games, sports, and leisure, and parts thereof, instruments, accessories, and apparatus for use in medicine or hygiene, and parts thereof, implants and prosthesis for use in medicine, and parts thereof, and constructions, and parts thereof, protective equipment and parts thereof, apparatus, auxiliaries, and devices for air and water treatment, production plants and parts thereof, or textile materials and parts thereof. Specific examples of applications for articles, appliances or constructions or parts thereof that may be provided, as substrates, with the coating comprising a one-dimensional composite structure are specified below.

Examples of constructions and parts thereof which may be provided with the layers are architectural facing elements, paneling, metal-sheet roofs, roofing shingles, blocks, and elements, construction blocks in general (brick, clinker bricks), roofs of all kinds, cement facings, wooden facings, glass facings, paving slabs, trafficway elements, trafficway slabs (e.g., composite slabs), sanitary ceramics (e.g., sinks, basins, tubs), garage doors, windows and doors, and also window frames and door frames, floors, walls, and ceilings, elements and paneling for industrial constructions (e.g., warehouses), urban furniture (e.g., bollards, benches, refuse boxes, garbage bins), signs (e.g., advertising, traffic signs), information displays, display cases, information kiosks, illumination elements, lamps and lighting, lamp shades, reflectors, glazing covers, especially those over halogen lamps, distributor boxes, barriers and barrier posts, reflectors (e.g., cat's eyes), surfaces for reflective and retroreflective sheets (e.g., in the traffic segment, on automobiles, etc.), telephone kiosks, projection walls (e.g., video walls, drive-in cinemas), garbage containers, cooling systems and heat exchangers (e.g., evaporator fins in air-conditioning equipment), greenhouses (glass), sound barriers (e.g., on highways), fountains, and noise prevention walls made of any materials.

Examples of means of locomotion and means of transport and parts thereof, which may be parts of the composite materials produced by means of the invention, are bodywork parts, trim elements and elements for external installation (e.g., spoilers, wheel-arch extensions), parts of cycles and motorcycles (e.g., frames, rims, and fairings), hoods, aircraft, boats, and superstructures and hulls thereof.

Examples of working equipment and parts thereof, which may comprise the composite materials produced by means of the invention, are construction machinery, optical sensors, sight glasses, apparatus for food-and-drink production, transport belts, conveying machines, production machines, and pipes.

Further possibilities include household articles and working equipment for the household, and parts of these. Examples thereof are coffee machines, kitchen appliances and culinary machines, cutlery, crockery, glasses, kitchen utensils, telephones, switches, and lamps.

Examples of other uses are as articles for fittings; apparatus and accessories for games, sport, and leisure, and parts thereof. They may be fencing, garden fences, and enclosures, cell phones, covers for clocks and watches (e.g., wrist watches, wall clocks or station clocks), photographic media; garden items, skis, snowboards, surfboards, golf clubs, and dumbbells.

Examples of devices, accessories and equipment for medical use, and parts thereof, are paneling and housings of medical devices, medical devices themselves, surgical instruments and tools, endoscope windows, dental equipment (e.g., treatment chairs, drills, hand parts, lamps), and implants.

Examples of apparatus, articles, and machines for commercial or industrial use, and research and laboratory, and parts thereof, are laboratory benches (e.g., for chemistry or biotechnology), work benches, microscopic supports, slides, superhydrophilic sensors (e.g., optical sensors, chemical sensors, and biological sensors), and optical instruments (e.g., microscopes, lenses, mirrors, windows).

The invention also relates to a method for joining at least two substrates.

In a first step, the two substrates are disposed such that at least one region of each of their surfaces is at a distance of not more than 20 μm, preferably not more than 15 μm, more preferably up to not more than 10 μm. The distance may also be between 100 nm and 10 μm.

Distance here denotes the shortest distance between the surfaces of pairs of substrates that intersects only once with each surface of the substrates.

Thereafter, on both substrates, as already described, a thermal decomposition is carried out, to form a one-dimensional composite structure. This procedure is accompanied by the growing of the one-dimensional composite structure on the surface of the two substrates. As already described, the structure of the one-dimensional composite structure can be controlled through the pressure, the substrate temperature, and the time. In order to achieve joining of the two substrates, it may be possible for the thermal decomposition to be carried out for a longer time.

The thermal decomposition is preferably carried out for 10 to 60 minutes at 450 to 600° C. under a pressure of between 2·10⁻² mbar and 5·10⁻² mbar. With advantage, of the substrates, the region heated is essentially the region which is to be joined to its counterpart region. In this way it is possible to prevent a one-dimensional composite structure being formed on other regions of the substrates.

This leads to a purely inorganic joining of the two substrates, which is also stable over a wide temperature range. In the case of an Al/Al₂O₃ composite structure, a stable join can be achieved for a temperature range from room temperature up to 600° C.

In one development of the invention, the joined substrate is additionally subjected to a temperature treatment. This is preferably a temperature treatment of between 700° C. and 1000° C., preferably between 700° C. and 800° C.

At these temperatures, the core of the element/element oxide composite structure, consisting of the element, melts and passes to the outside. This process is accompanied by formation of new one-dimensional composite structures, which carry new joins between the existing composite structures. As a result, the joining between the substrates is strengthened further. The temperature treatment may also be carried out by laser or plasma.

The temperature treatment is carried out preferably for a number of hours—for example, between 1 and 10, preferably between 1 and 5, hours.

In the course of the temperature treatment, further nanowires are formed, owing to the core/shell construction of the one-dimensional composite structure, and this strengthens the join between the two substrates.

Joining can also be achieved by contacting two substrates with a coating comprising a one-dimensional composite structure, and, as described, carrying out heat-treatment. In this way as well, a laminate with a purely inorganic bonding layer is formed.

Substrates which can be used are all substrate which withstand the conditions of the thermal decomposition.

The invention further relates to a coating on a substrate comprising an inorganic one-dimensional composite structure which is an element/element oxide structure and has a thickness of below 300 nm, preferably between 50 and 300 nm, more preferably between 100 and 300 nm.

The invention further relates to the use of a coating comprising a one-dimensional composite structure for controlling the adhesion capacity of the surface coated with the coating. The coating can be used preferably for controlling the bonding of adhesive agent on substrates. This may also relate only to parts of the surface of substrates. The coating comprising a one-dimensional composite structure may in this context increase the adhesion or else—as described—reduce it. Increasing the adhesion is preferred.

The invention relates, furthermore, to a composite material which comprises a one-dimensional composite structure in a matrix. By the incorporation of the inorganic one-dimensional composite structure it is possible in particular to increase the hardness of the matrix material.

The matrix in question is advantageously an organic matrix, and hence the composite material is an organic-inorganic composite material. The matrix is more particularly an organic polymer, which may be linear or branched. Polymers here are resins, polycarbonates, aromatic polyesters, such as PET, PEN or PETG, for example, acrylates or methacrylates such as PMMA, for example, and also polyolefins. They may also be copolymers or mixtures of the stated polymers. Preferred are acrylates, polymethyl methacrylates, or polyvinyl acrylates.

The composite material may be produced in a way similar to the production of the above-described composite material for the adhesive bonding of substrates. For this purpose, first of all, a coating comprising a one-dimensional composite structure is produced on a substrate. This is done, as already described, by the thermal decomposition of a precursor on the surface of a substrate, to form a one-dimensional composite structure.

A matrix former is applied to this one-dimensional composite structure on the surface of the substrate. The matrix former is a composition which can be transformed into the matrix of the composite material. This may take place by chemical and/or by physical operations, such as, for example, chain-growth polymerization, polycondensation, or else by evaporation of solvent from the composition.

In the case of a chain-growth polymerization or polycondensation, the composition may comprise monomers, oligomers or polymers which are able to polycondense or polymerize to form the matrix, more particularly by means of polymerizable and polycondensable groups.

As matrix formers it is possible to use organic polymers known to the skilled person, examples being polyacrylic acid, polymethacrylic acid, polyacrylates, polymethacrylates, polyolefins, such as polybutadiene, polystyrene, polyamides, polyimides, polyvinyl compounds, such as polyvinyl chloride, polyvinyl alcohol, polyvinylbutyral, polyvinyl acetate, and corresponding copolymers, an example being poly(ethylene-vinyl acetate), polyesters, such as polyethylene terephthalate or polydiallyl phthalate, polyarylates, polycarbonates, polyethers, such as polyoxymethylene, polyethylene oxide, or polyphenyl oxide, polyether ketones, polysulfones, polyepoxides, and fluoropolymers, an example being polytetrafluoroethylene. It is also possible to use precursors of these. Contained with preference are functional groups via which crosslinking is possible.

Examples of such groups include epoxide, hydroxyl, ether, amino, monoalkylamino, dialkylamino, optionally substituted amino, amide, carboxyl, vinyl, allyl, alkynyl, acryloyl, acyloxy, methacryloyl, methacryloyloxy, mercapto, cyano, alkoxy, isocyanato, aldehyde, alkylcarbonyl, acid-anhydride, and phosphoric acid group.

The matrix former may also comprise further additives which are added in the art customarily according to purpose and to desired properties.

Specific examples are thixotropic agents, crosslinking agents, solvents, dyes, UV absorbers, lubricants, flow control agents, wetting agents, adhesion promoters, and initiators.

Suitable initiators include all familiar initiators/initiator systems that are known to the skilled person, including radical photoinitiators, radical thermoinitiators, cationic photoinitiators, cationic thermoinitiators, and any desired combinations thereof.

Depending on the composition of the matrix former, a curing procedure may be performed. This may be accomplished, for example, by irradiation or by heat treatment.

Curing of the matrix former is accompanied by a formation of the matrix. As a result of the enveloping of the one-dimensional composite structure with the matrix, the composite material is formed.

After the cure, the composite material is detached from the surface of the substrate. At least part of the one-dimensional composite structure which is incorporated in the organic matrix is detached along with the material. The composite material obtained may also comprise only the surface of the cured matrix.

With advantage the one-dimensional composite structure is a composite structure which has only a low adhesion, like the composite structures which have been deposited over 10 minutes. In this case, the adhesive agent corresponds to the matrix former. Application of the adhesive agent corresponds to the formation of the matrix. During detachment, the forces of adhesion between adhesive agent and one-dimensional composite structure are stronger than the bonding of the composite material to the substrate or to that part of the one-dimensional composite structure which has not been incorporated into the matrix.

In this way, the one-dimensional composite structure may be incorporated into a matrix. The resulting composite material may have not only an increased hardness. In this way, the structure of the one-dimensional composite structure can also be transposed to the composite material. The surface of the composite material that is produced may thus also exhibit particular properties, such as modified adhesion.

The invention also relates to an apparatus for implementing MOCVD, more particularly for producing the one-dimensional composite structure. The apparatus includes all of the features of an MOCVD apparatus that are known to the skilled person. These features have already been elucidated in more detail in the context of the description of producing the one-dimensional composite structure. A contrivance or apparatus of this kind, in addition to the constituents already described, has at least one CVD chamber (reaction tube), a precursor inlet, and a sample holder. The sample holder is used to fix the substrate in the precursor stream. The sample holder usually has a surface adapted accordingly, allowing the attachment of a substrate. In conventional CVD apparatus, the precursor stream runs horizontally in the CVD chamber—that is, the precursor passes from the reservoir vessel into the CVD chamber, and diffuses over the sample holder and the substrate applied thereto, the thermal decomposition of the precursor taking place on the surface of the substrate. The precursor that has not undergone decomposition is removed by the vacuum system attached to the CVD chamber on the output side. In order to achieve efficient and uniform thermal decomposition on the substrate, the surface of the sample holder on which the substrate is applied is inclined by 30° to 45° relative to the gas stream. This enables a long contact time between the thermal precursor and the substrate. Since the substrates treated by CVD are usually planar, the substrate surface to be treated is also disposed at a similar angle relative to the precursor stream. In the contrivance or apparatus of the invention, the precursor stream is disposed vertically. In this case, depending on the orientation of the precursor inlet, there may also be a deviation from the vertical of up to 20°. Irrespective of the course of the precursor stream before or after the CVD chamber, “vertical” here denotes the orientation of the precursor stream in the region of the CVD chamber in which the thermal decomposition takes place. The precursor is advantageously passed into the CVD chamber above the sample holder. In that case, accordingly, the vacuum system is disposed below the sample holder.

Moreover, the surface of the sample holder on which the substrate has been applied is disposed such that the precursor stream strikes this surface at an angle of between 70° and 120°, preferably between 80° and 110°, more preferably between 85° and 105°, very preferably 90°. This applies particularly to planar substrates.

For a uniform coating it is also essential that the precursor stream as well strikes the surface of the applied substrate in the same angular ranges. Depending on the shape of the substrate, it is also possible for the angular range to be achieved only for part of the surface. The angular ranges are advantageously achieved for at least 70% of the substrate surfaces to be treated.

In a further embodiment, the substrate holder may be mounted rotatably and hence allow the substrate to be rotated.

In a further embodiment of the invention, the precursor is passed into the CVD chamber via a nozzle. Advantageously this is a temperature-conditioned nozzle, so that the decomposition of the precursor can be prevented. The temperature-conditioning techniques involved may be any of those known to the skilled person, such as, for example, cooling by passage of fluid, such as water or oil. Instead of cooling, the nozzle may also be heated to a defined temperature. It is important that the temperature of the nozzle can be kept constant over the period of the thermal decomposition.

In a further embodiment of the invention, the means for the heating of the substrate are located within the CVD chamber. These means may be, for example, a coil which emits a radiofrequency field. As a result it is possible to control the temperature of the substrate even more precisely.

Further details and features will become apparent from the description below of preferred exemplary embodiments in connection with the dependent claims. In this context, the respective features may each be actualized on their own or in plurality in combination with one another. The possibilities for achieving the object are not confined to the exemplary embodiments. For example, range indications always encompass in-between values—not specified—and all conceivable subintervals.

The exemplary embodiments are shown diagrammatically in the figures. Identical reference numerals in the individual figures denote identical or functionally identical elements or elements which correspond to one another in terms of their functions. Specifically:

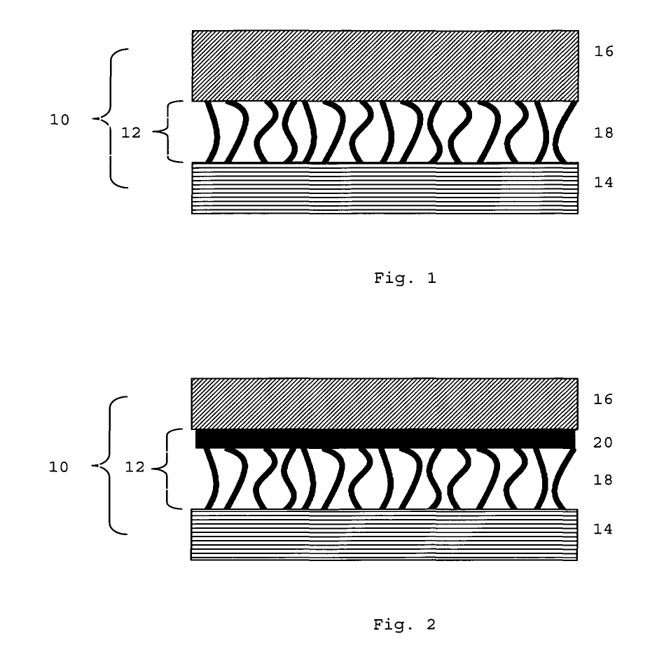

FIG. 1 shows a diagrammatic representation of a laminate 10 having a bonding layer 12 comprising a one-dimensional composite structure 18;

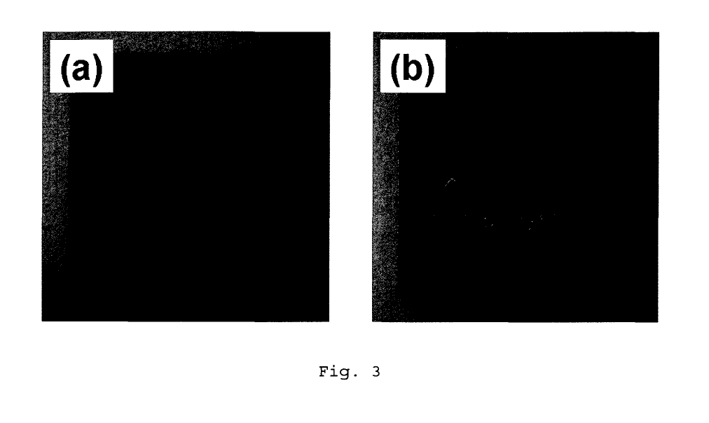

FIG. 2 shows a diagrammatic representation of a laminate 10 having a bonding layer 12 comprising a one-dimensional composite structure 18 and an adhesive agent 20;

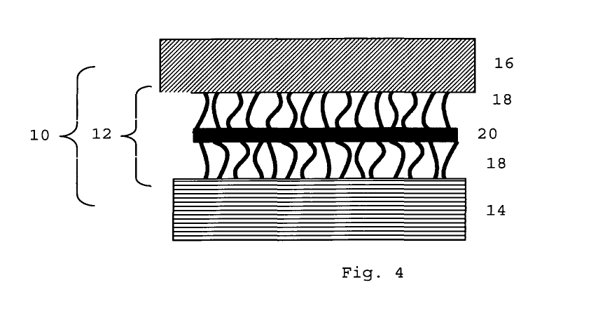

FIG. 3 shows photographs of a glass substrate coated with a one-dimensional composite structure (a) before the application of a pressure-sensitive adhesive tape, to form a laminate, and after the removal of this adhesive tape (b); the arrow shows residues of the layer of adhesive agent on the glass;

FIG. 4 shows a diagrammatic representation of a laminate comprising two substrates, coated with a one-dimensional composite structure, and a pressure-sensitive adhesive agent;

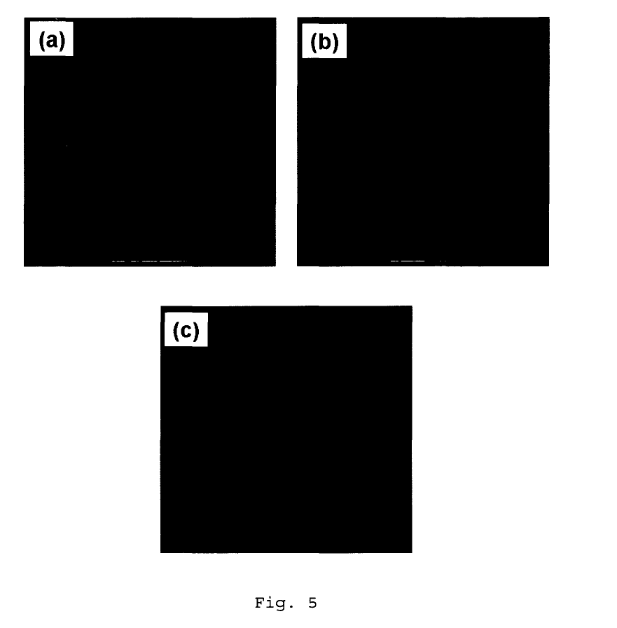

FIG. 5 shows SEM micrographs (SEM: scanning electron microscope) of the one-dimensional composite structure with nanowires in low (a), medium (b), and high (c) density;

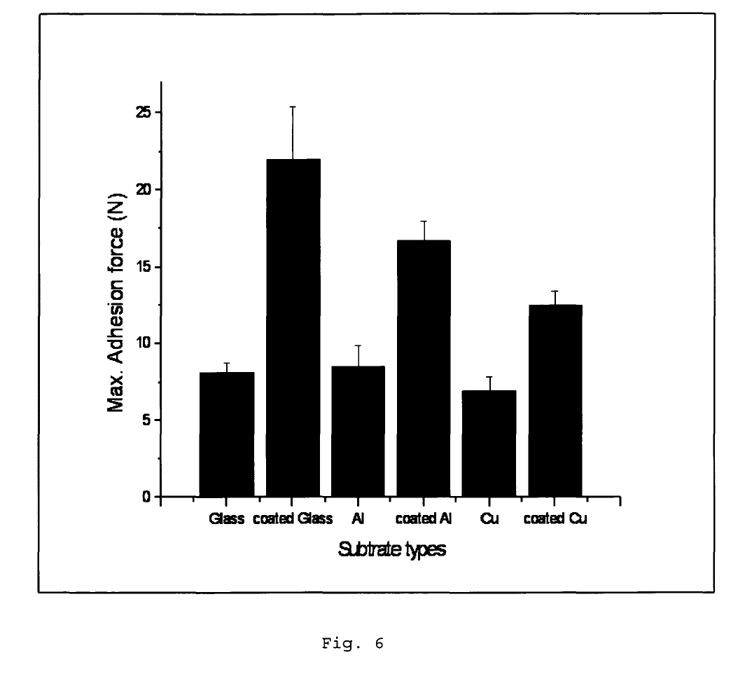

FIG. 6 shows measurement of the adhesion for laminates comprising various substrates and a pressure-sensitive adhesive agent with and without a one-dimensional composite structure;

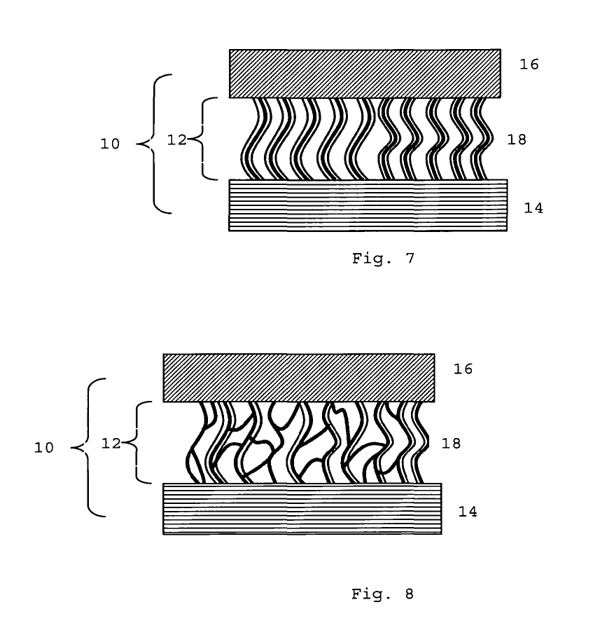

FIG. 7 shows a diagrammatic representation of the joining of two substrates via a one-dimensional composite structure;

FIG. 8 shows a diagrammatic representation of the design of further nanowires of two substrates, joined via a one-dimensional composite structure, by means of a heat-treatment;

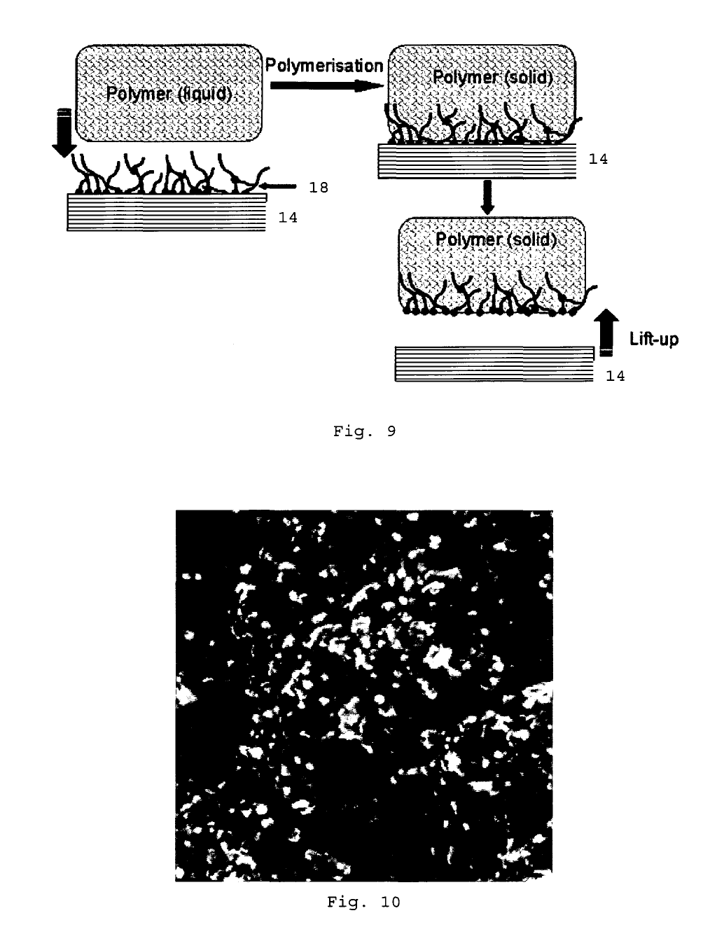

FIG. 9 shows a diagrammatic representation of the transfer of a one-dimensional composite structure to a different substrate;

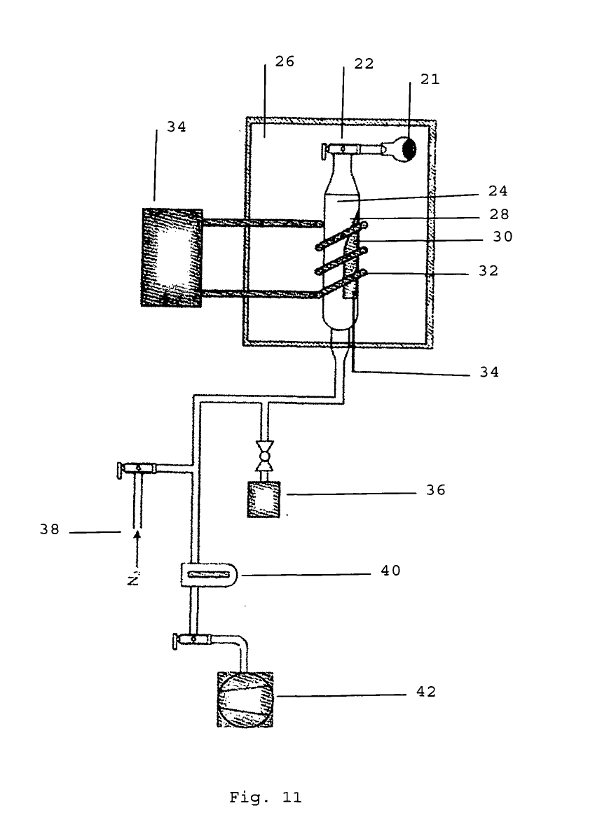

FIG. 10 shows an SEM micrograph of a one-dimensional composite structure in a matrix of PMMA (polymethyl methacrylate);

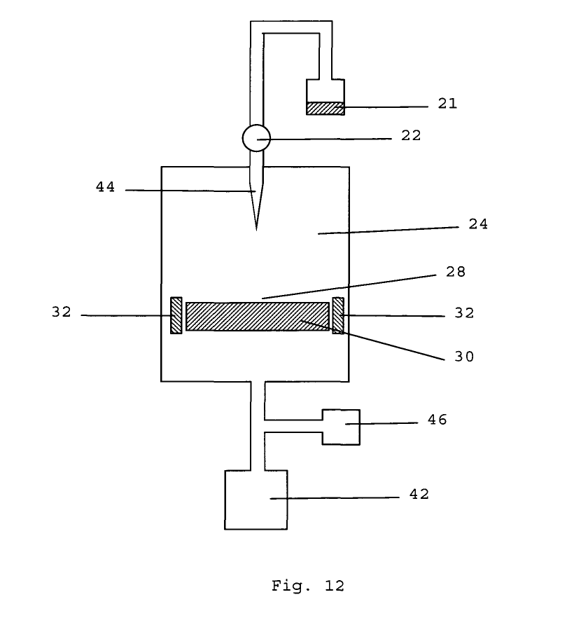

FIG. 11 shows a diagrammatic representation of the MOCVD apparatus or contrivance from the prior art;

FIG. 12 shows a diagrammatic representation of a MOCVD apparatus or contrivance in accordance with the invention.

FIG. 1 shows, diagrammatically, a laminate 10 comprising two substrates 14 and 16, which are joined via a bonding layer 12 comprising a one-dimensional composite structure 18.

FIG. 2 shows, diagrammatically, a laminate 10 comprising two substrates 14 and 16, which are joined via a bonding layer 12 comprising a one-dimensional composite structure 18 and an adhesive agent 20. This adhesive agent 20 is applied to the second substrate (16) and joins to the one-dimensional composite structure 18 when the substrates are pressed together. With advantage it is a pressure-sensitive adhesive agent.

FIG. 3 shows the effect of the one-dimensional composite structure on the adhesion of a laminate comprising a glass substrate, a bonding layer comprising a one-dimensional composite structure and a pressure-sensitive adhesive agent, and the carrier of the adhesive agent (the adhesive agent and the carrier together form an adhesive tape). FIG. 3a shows the glass substrate before the laminate is formed. If, after the laminate has been produced, an attempt is made to remove the adhesive tape, i.e., to part the laminate again, a large part of the adhesive agent of the adhesive tape remains on the coated surface when the adhesive tape is detached (FIG. 3b). This means that the adhesion of the adhesive agent to the one-dimensional composite structure is in each case higher than the adhesion between carrier and adhesive agent.

FIG. 4 shows a laminate 10 with a bonding layer 12, which comprises one-dimensional composite structures 18 and a pressure-sensitive adhesive agent 20. In this case, a one-dimensional composite structure 18 was disposed on the surface of the first substrate 14 and the surface of the second substrate 16. It may also be the case that the adhesive agent 20 comprises a double-sided adhesive tape, i.e., a carrier which is coated with an adhesive agent on both sides. In this case there would be two laminates one on top of the other.

FIG. 5 shows SEM micrographs of coatings comprising a one-dimensional composite structure having different adhesion properties. The coatings were generated by thermal decomposition of (tert-BuOAlH₂)₂. FIG. 5a shows a low-density coating of the one-dimensional composite structure. These are one-dimensional composite structures having a thickness of below 300 nm, preferably between 50 and 300 nm, more preferably below 150 nm or between 50 and 150 nm. Such coatings exhibit a durable adhesion. The adhesive forces in relation to applied adhesive agents are greatly increased. FIG. 5b shows a medium-density coating of one-dimensional composite structure. FIG. 5c shows a one-dimensional composite structure with a high density. A coating of this kind exhibits a significantly reduced adhesion in relation to applied adhesive agents.

The low-density, medium-density and high-density one-dimensional composite structures can be distinguished on the basis of the thickness of the coating (measured by SEM). A one-dimensional composite structure having a thickness of below 300 nm, preferably below 150 nm, has a low density of one-dimensional composite structure. A medium-density composite structure has a thickness of between 300 and 500 nm. The high-density one-dimensional composite structure is distinguished by a thickness of more than 500 nm.

FIG. 6 shows various measurements of the adhesive force (ASTM D 3330) for coated and uncoated substrates of different materials (glass, aluminum, copper). Here, in each case, a coating comprising a one-dimensional composite structure of low density was produced, after which the adhesive force was measured. In all samples there is a clear increase in adhesion as a result of the coating.

FIG. 7 shows, diagrammatically, the joining of two substrates (14, 16) to form a laminate 10 by the growth thereon of a one-dimensional composite structure 18. The thermal decomposition is accompanied by the formation of a one-dimensional composite structure which is able to join the two substrates. This is also possible by virtue of the fact that the one-dimensional composite structure can have nanowires with a length of several micrometers, especially after prolonged thermal decomposition. As a result of this, crosslinking of the two one-dimensional composite structures can occur between the two substrates, which are disposed only at a small distance from one another. In that case the bonding layer 12 consists exclusively of the one-dimensional composite structure.

FIG. 8 shows, diagrammatically, the consequence of a further temperature treatment of the connection from FIG. 7. As a result of this further treatment there is a branching of the one-dimensional composite structure 18, and an even greater crosslinking.

FIG. 9 shows the diagrammatic sequence of the production of a composite material comprising a one-dimensional composite structure in a matrix. In a first step, a liquid polymer (matrix former) is applied to a coating comprising a one-dimensional composite structure. The polymer is polymerized. As a result, a solid matrix is formed which encases the one-dimensional composite structure. When the solidified matrix is detached, the incorporated one-dimensional composite material is detached. A polymer is obtained which in part of the surface has a composite material comprising a one-dimensional composite structure in a matrix.

FIG. 10 shows an SEM micrograph of a one-dimensional composite structure incorporated into polymethyl methacrylate.

FIG. 11 shows a customary apparatus for the implementation of MOCVD. With such an apparatus it is possible to produce one-dimensional composite structures in accordance with the invention. In the apparatus shown, the precursor 21 passes via a valve 22 into the CVD chamber 24 (CVD: chemical vapor deposition). There, thermal decomposition takes place on the substrate 28, which has been applied to a sample holder 30. The surface 28 of the sample holder on which the substrate is applied is inclined by 30° to 45° relative to the gas stream. This is so that the precursor diffuses with maximum uniformity over the surface on which the decomposition is to take place. In the case of a vertical surface, the deposition will be nonuniform. The sample holder 30 is heated to the required temperature via a coil 32 and a radiofrequency generator 34 connected to said coil. This coil is located outside the CVD chamber. The temperature of the substrate is monitored with a temperature sensor 34. The entire apparatus may also be disposed in an oven 26, in order to heat the precursor to a particular temperature. Connected to the apparatus on the side opposite the inlet of the precursor 22 is a vacuum pump 42. Before the pump there may also be a cold trap 40.

Moreover, a mass spectrometer 36, additionally, may optionally be attached to the sample chamber. A further inflow 38 may be provided for flooding the apparatus with a gas. By this means it is possible to flood the apparatus with an inert gas, such as nitrogen or argon, for example, prior to use.

FIG. 12 shows the diagrammatic construction of a preferred apparatus for producing the one-dimensional composite structure. The apparatus permits particularly precise control of the thickness, or the thickness of the one-dimensional composite structure on the substrate. The apparatus may include all of the components of a customary CVD apparatus, as illustrated by way of example in FIG. 11, although these are not shown in the diagram. The essential difference on the part of the apparatus of the invention lies in the disposition of the constituents of the apparatus within the CVD chamber 24. In contrast to the apparatus from FIG. 11, a feature of this CVD chamber is that the stream of the precursor runs vertically through the CVD chamber. The inlet of the precursor 22 is preferably disposed above the sample holder. The connection to the vacuum pump 42 is disposed opposite the inlet. Moreover, the area on which the substrate is applied, 28, on the sample holder 30 is disposed substantially perpendicular to the precursor stream. This means that it is disposed with an angle of between 70° and 120°, preferably between 80° and 110°, more preferably 90°, with respect to the precursor stream. The sample holder is advantageously arranged rotatably.

The sample holder 32 can advantageously be heated within the CVD chamber. In this way, the temperature of the substrate can be monitored more precisely. With advantage, the precursor is introduced into the sample chamber not via a tube, but instead via a nozzle 44, which optionally has its own cooling. By this means it is possible to prevent the decomposition of the precursor in the apparatus, which could occur as a result of the heat given off in radiation by the substrate. The nozzle 44 is advantageously connected to a water cooling facility. Furthermore, the apparatus may also have a pressure sensor 46. In this way it is possible to monitor precisely the parameters of the thermal decomposition.

### WORKING EXAMPLES

Thin films of the one-dimensional composite structure were applied to heated substrates by MOCVD of the precursor (^{t}BuOAlH₂)₂. This precursor was prepared as described in Veith et al. Chem. Ber. 1996, 129, 381-384.

The adhesion measurements were carried out according to a standard test (ASTM D 3330).

### Example 1

### Durable Adhesion

Glass substrates were heated to 450 to 600° C. and exposed to a stream of (tBuOAlH₂)₂ for 1 to 5 minutes under a pressure of between 2·10⁻² mbar and 5·10⁻² mbar. A one-dimensional composite structure was obtained with a low density of nanowires (FIG. 5a). In adhesion measurements, this coating exhibits a durable adhesion. The adhesive agent layer of the pressure-sensitive adhesive tape used remains on the surface of the coating on removal (FIG. 3b).

### Example 2

### Controlled Adhesion

Glass substrates were heated to 450 to 600° C. and exposed to a stream of (^{t}BuOAlH₂)₂ for 5 to 10 minutes under a pressure of between 2·10⁻² mbar and 5·10⁻² mbar. A one-dimensional composite structure was obtained with a medium density of nanowires (FIG. 5b). In adhesion measurements, this coating exhibits a reduced adhesion. The adhesive agent layer of the pressure-sensitive adhesive tape used remains partly on the surface of the coating on removal. However, much less than in example 1.

### Example 3

### No Adhesion

Glass substrates were heated to 450 to 600° C. and exposed to a stream of (^{t}BuOAlH₂)₂ for 10 to 60 minutes under a pressure of between 2·10⁻² mbar and 5·10⁻² mbar. A one-dimensional composite structure was obtained with a high density of nanowires (FIG. 5c). In adhesion measurements, this coating exhibits a greatly reduced adhesion. The one-dimensional composite structure is detached by the removal of the adhesive tape. The coating exhibits only a very low adhesion. Even on multiple sticking, the adhesion remains very low, or there is no adhesion at all.

### Example 4

### Joining of Two Substrates

Two substrates of metal were arranged parallel to one another with a distance of a few micrometers. The substrates were heated to 450 to 600° C. and exposed to a stream of (^{t}BuOAlH₂)₂ for 10 to 60 minutes under a pressure of between 2·10⁻² mbar and 5·10⁻² mbar. The two substrates were joined by the growth thereon of the one-dimensional composite structure.

### Example 5

Two substrates of metal were treated as in example 4 and subsequently heated at 750° C. for 1 to 5 hours. As a result of this heating there is a further increase in the adhesion between the two substrates.

### Example 6

Methyl methacrylate monomer (MMA (Aldrich)), benzoyl peroxide (BPO (Fluka)), and N,N-dimethyl-p-toluidine (DMPTA (Fluka)) were used as obtained. A monomer composition with 0.8% w/w of DMTPA (w denotes % by weight) and 1% w/w of BPO in the monomer was prepared. This composition was applied at room temperature to a steel substrate which had been coated with an Al/Al₂O₃ composite structure. Thereafter the composition was polymerized at 80° C. At the surface of the polymer, the composite structure is incorporated into the polymer matrix. After the polymerization, the polymer matrix formed is detached from the substrate. In the course of this process, the composite structure as well is parted from the substrate. In this way, the composite structure can be transferred to a polymer substrate.

Numerous modifications and developments of the working examples described can be realized.

### LITERATURE CITED

WO 01/49776 A2
U.S. Pat. No. 6,099,960
DE 10 2006 013 484 A1

### REFERENCE SYMBOLS

10 laminate
12 bonding layer
14 first substrate
16 second substrate
18 one-dimensional composite structure
20 adhesive agent and/or bonding agent
21 precursor in the reservoir vessel
22 valve/inlet for the precursor
24 CVD chamber
26 oven
28 surface of the sample holder
30 sample holder
32 means for heating the sample holder/coil
34 radiofrequency generator
36 mass spectrometer
38 inflow for inert gas
40 cold trap
42 vacuum pump
44 nozzle
46 pressure sensor

1. A laminate comprising at least two substrates, wherein between the two substrates there is a bonding layer which comprises at least one one-dimensional composite structure.

2. The laminate of claim 1, wherein the one-dimensional composite structure comprises an element/element oxide composite structure.

3. The laminate of claim 2, wherein the element is selected from the group consisting of Al, Ga, In, Tl, Si, Ge, Sn, Pb and Zr.

4. The laminate of claim 1, wherein the bonding layer comprises an adhesive agent and/or bonding agent.

5. The laminate of claim 4, wherein the adhesive agent and/or bonding agent comprises a pressure-sensitive adhesive agent and/or bonding agent.

6. The laminate of claim 1, wherein the bonding layer consists only of inorganic constituents.

7. The laminate of claim 6, wherein the bonding layer consists only of at least one one-dimensional composite structure.

8. A method for joining at least two substrates comprising:
a) disposing the substrates so that at least one region of each of their surfaces is disposed at a distance of not more than 20 μm from the other;
b) thermally decomposing a precursor on the surface of the substrates, to form a one-dimensional composite structure between the substrates.

9. The method of claim 8, wherein the substrates after step b) are additionally subjected to a temperature treatment.

10. A composite material comprising a one-dimensional composite structure in a matrix.

11. The composite material of claim 10, wherein the matrix is an organic matrix.

12. A method for producing a composite material, comprising:
a) thermally decomposing a precursor on the surface of a substrate, to form a one-dimensional composite structure;
b) applying a matrix former to the surface with the one-dimensional composite structure;
c) curing the matrix former, to form a composite material;
d) detaching the composite material from the surface of the substrate.

13. A method for producing a laminate having at least two substrates with controlled adhesion between the substrates, comprising:
a) thermally decomposing a precursor on the first of the substrates, to form a one-dimensional composite structure;
b) contacting the one-dimensional composite structure with an adhesive agent, which may have been applied to the surface of a second substrate or which is contacted with the second substrate in a further step, the conditions of the thermal decomposition, selected from pressure, temperature, and duration of the thermal decomposition, being used to control the strength of the adhesion mediated by the laminate between the at least two substrates.

14. The method of claim 13, wherein the precursor comprises a compound of the general formula
El(OR)ₙH₂
where El is Al, Ga, In, Tl, Si, Ge, Sn, Pb, or Zr, and R is an aliphatic or alicyclic hydrocarbon radical, and n, depending on the valence of El, has a value of 1 or 2.

15. The method of claim 13, wherein the adhesive agent (20) is a pressure-sensitive adhesive agent.

16. A coating on a substrate comprising an inorganic one-dimensional composite structure, wherein the composite structure is an element/element oxide structure and has a thickness of below 300 nm.

17. The coating of claim 16, wherein the coating comprises a pressure-sensitive adhesive agent and/or bonding agent.

18. (canceled)

19. An apparatus for performing metal organic chemical vapor deposition, comprising:
at least one CVD chamber,
a precursor inlet, and
a sample holder which has a surface,
wherein the stream of a precursor runs vertically in the CVD chamber and strikes the surface of the sample holder at an angle of between 80° and 120°.

20. The apparatus of claim 19, wherein the precursor is passed via a thermally conditioned nozzle into the CVD chamber.

21. The apparatus of claim 19, wherein the apparatus has means for the heating of the substrate that are disposed within the CVD chamber.

22. A method for controlling the adhesion capacity of a surface comprising applying a coating comprising a one-dimensional composite structure as claimed in claim 16.
